(19) United States
(12) Patent Application Publication
(10) Pub. No.: US 2023/0197565 A1
(43) Pub. Date: Jun. 22, 2023

(54) REMOTE MECHANICAL ATTACHMENT FOR BONDED THERMAL MANAGEMENT SOLUTIONS

(71) Applicants: Jerrod P. Peterson, Hillsboro, OR (US); Kyle J. Arrington, Gilbert, AZ (US); Ellann Cohen, Beaverton, OR (US); Mark A. MacDonald, Hillsboro, OR (US); Christopher Michael Moore, Hillsboro, OR (US); Akhilesh P. Rallabandi, Portland, OR (US)

(72) Inventors: Jerrod P. Peterson, Hillsboro, OR (US); Kyle J. Arrington, Gilbert, AZ (US); Ellann Cohen, Beaverton, OR (US); Mark A. MacDonald, Hillsboro, OR (US); Christopher Michael Moore, Hillsboro, OR (US); Akhilesh P. Rallabandi, Portland, OR (US)

(21) Appl. No.: 18/090,420

(22) Filed: Dec. 28, 2022

(51) Int. Cl. H01L 23/427; H01L 23/00; H05K 7/20; H05K 1/18

(52) U.S. Cl. CPC H01L 23/427; H01L 24/29; H01L 24/32; H05K 7/20336; H05K 7/20154; H05K 1/18; H01L 2224/32245; H01L 2224/2929; H01L 2924/0665; H01L 2224/29291; H01L 2924/0715; H01L 2224/29347; H01L 2224/29339; H01L 2224/29324; H01L 2224/29393; H01L 2224/29387; H01L 2924/0503; H01L 2224/29317; H01L 2924/01033; H01L 2924/01327; H01L 2924/05032; H01L 2924/05432; H01L 2224/29305; H01L 2224/29309; H01L 2224/29311; H01L 2224/29318; H01L 2924/0133; H01L 2224/29313; H01L 2924/014; H05K 2201/066

(57) ABSTRACT

A thermal management solution in a mobile computing system is bonded to an integrated circuit component by a thermal interface material layer (TIM layer) that does not require the application of a permanent force to ensure a reliable thermally conductive connection. A leaf spring or other loading mechanism that can apply a permanent force to a TIM layer can be secured to a printed circuit board by fasteners that extend through holes in the board in the vicinity of the integrated circuit component. These holes consume area that could otherwise be used for signal routing. In devices that use a TIM layer that does not require the application of a permanent force, the thermal management solution can be attached to a printed circuit board or chassis at a location remote to the integrated circuit component, where the attachment mechanism does not or minimally interferes with integrated circuit component signal routing.

### BACKGROUND

Some thermal interface materials (TIMs) require the application of a permanent force to the TIM to ensure a reliable low thermal resistance connection. In some designs, the permanent force to the TIM is applied by leaf springs that are secured to a printed circuit board in part by fasteners that extend through holes in the printed circuit board.

### BRIEF DESCRIPTION OF THE DRAWINGS

FIG. 1 illustrates an exploded view of a structure in which a permanent force is applied to the heat sink of a thermal management solution.

FIG. 2 illustrates an exploded view of a first example structure comprising a thermal management solution directly bonded to an integrated circuit component by a TIM layer.

FIG. 3 illustrates an exploded view of a second example structure comprising a thermal management solution directly bonded to an integrated circuit component by a TIM layer.

FIG. 4 illustrates an exploded view of a third example structure comprising a thermal management solution directly bonded to an integrated circuit component by a TIM layer.

FIG. 5 illustrates an exploded view of a fourth example structure comprising a thermal management solution directly bonded to an integrated circuit component by a TIM layer.

FIG. 6 is a block diagram of an example computing system within which the technologies described herein can be utilized.

### DETAILED DESCRIPTION

Thermal management solutions in mobile computing systems, such as laptops, can require significant loads (˜20 psi) to provide a high-quality and reliable thermal interface resistance to an integrated circuit component (such as a central processing unit (CPU) or system-on-a-chip (SoC), to be cooled by the thermal management solution. Some existing thermal management solutions for mobile computing systems are attached to a printed circuit board by screws that extend through holes in the board or nuts that are mounted to a surface of the board. These attachment points are located near the integrated circuit component to be cooled by the thermal management solution. As such, they can interfere with the routing of signals in the breakout region of the printed circuit board associated with an integrated circuit component and the placement of other components (e.g., memory, voltage regulators, inductors) on the board in the vicinity of the integrated circuit component. This can drive up printed circuit board sizes and reduce the amount of printed circuit board area available for fans, batteries, and other components. The consumption of printed circuit board real estate by thermal management solution attachment points near an integrated circuit component is of particular concern in thin system designs where there is a strong need to enable smaller boards, larger batteries and fans, and optimal memory routing and trace lengths. Further, competitive pressure to lower the thickness of mobile computing systems can limit the thickness available for a heat sink to the point where achieving a desired amount of mechanical loading on the thermal interface material (TIM) is becoming more and more challenging. That is, heat sinks are less capable of supporting an applied permanent force as heat sink thickness is reduced. This is of particular concern in mobile computing systems that have aggressively thin form factors, such as ultra-thin laptops.

Disclosed herein are thermal management solutions that comprise a heat sink directly bonded to an integrated circuit component by a TIM layer and that are mechanically attached to a printed circuit board or system chassis at points remote to the component, such as beyond a breakout region associated with an integrated circuit component being cooled by the thermal management solution. These attachment points can be along structural extensions of the heat sink, at points along a heat transfer device comprising an internal cavity containing a working fluid (such as a heat pipe or vapor chamber), and/or at a remote heat exchanger or heat spreader. The attachment mechanisms can comprise brackets, tabs, screws, clips, compression pads, pressure-sensitive adhesives, other suitable mechanisms, or any combination thereof.

The use of TIM layers that can provide a strong mechanical connection having a low thermal resistance can eliminate the need for a sufficiently thick heat sink capable of applying a permanent load to the TIM layer and the local thermal management solution attachment mechanisms that can consume printed circuit board area. These TIM layers can comprise thermally conductive adhesive or low-temperature solders. The remote attachment of a thermal management solution to the printed circuit board and/or chassis can provide resistance to vibration and shock events that a mobile computing system can experience.

The direct bonding of a thermal management solution to an integrated circuit component and the remote attachment of the thermal management solution to a printed circuit board or system chassis have at least the following advantages. First, a reliable low thermal resistance connection can be made between a heat sink and an integrated circuit component without the need for a permanent load to be applied to the heat sink. Second, heat sinks that do not need to have a requisite stiffness to transfer a load applied to the heat sink by a leaf spring (or another component) to the TIM layer can be made thinner, which may enable thinner computing systems. Third, by anchoring a thermal management solution at one or more locations remote to an integrated circuit component being cooled (such as beyond a breakout region associated with the integrated circuit component), the mechanical stress experienced at the bonded thermal interface between the heat sink and the integrated circuit component can be lowered, which can aid in TIM layer survivability under vibration and shock event conditions. Fourth, by remote anchoring the thermal management solution at one or more locations remote to an integrated circuit component may not interfere with signal routing in the breakout region associated with the integrated circuit component being cooled. This may enable smaller and/or thinner printed circuit boards.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or in any other manner. “Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to embodiments of the present disclosure, are synonymous.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims

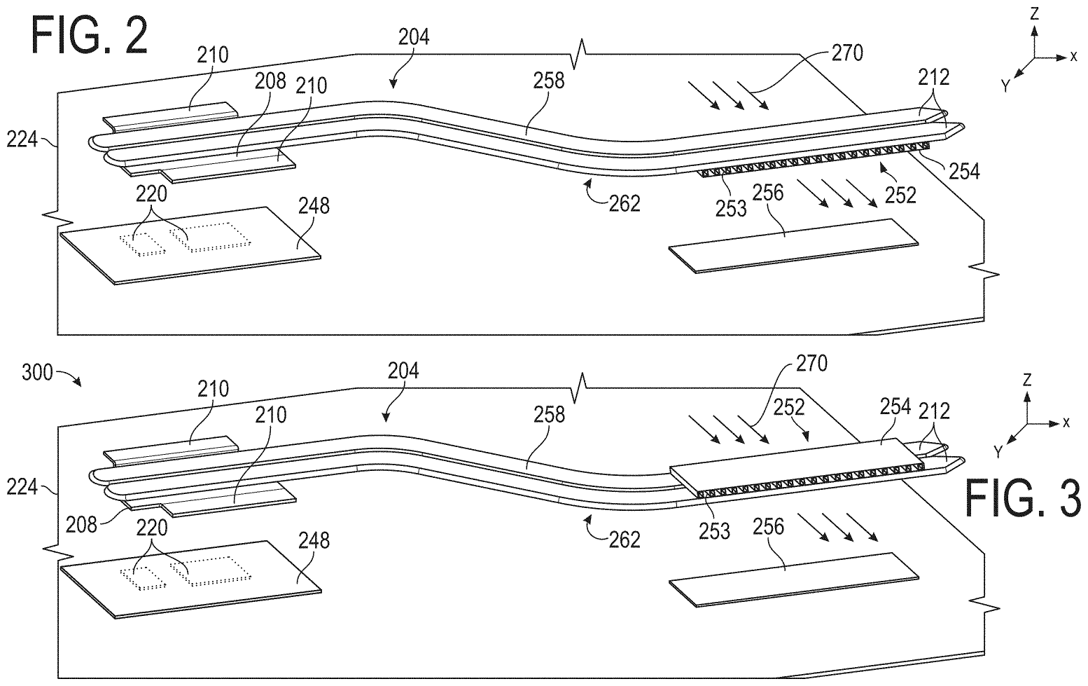

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. For example, with reference to FIGS. 2-5, the heat sink is located on the integrated circuit component (with an intervening TIM layer).

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

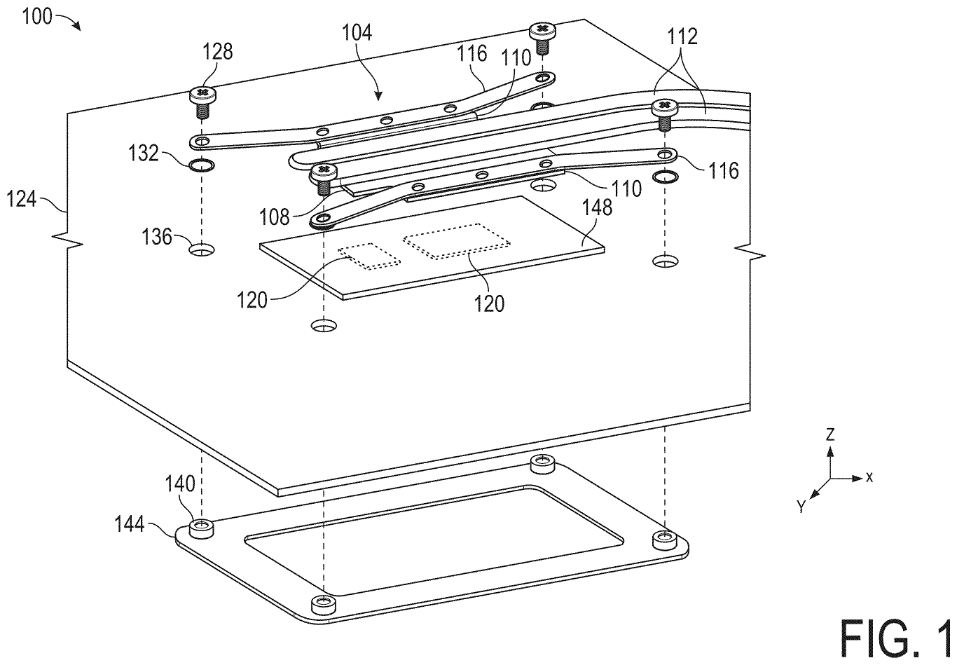

FIG. 1 illustrates an exploded view of a structure in which a permanent force is applied to the heat sink of a thermal management solution. The structure 100 comprises a thermal management solution 104 comprising a pair of heat pipes 112 attached to a heat sink (or cold plate) 108. The heat pipes 112 transport heat generated by an integrated circuit component 148 to a remote heat exchanger (not shown) or a remote heat spreader (not shown). The heat pipes 112 comprise a cavity containing a working fluid that aids in the transport of heat by transitioning between its liquid and gas phases.

The integrated circuit component 148 is attached to a printed circuit board 124 and is a packaged component comprising integrated circuit dies 120. A layer of thermal interface material (TIM layer, not shown in FIG. 1) is disposed between the heat sink 108 and the integrated circuit component 148 to provide a low thermal resistance path between these two components. The leaf springs 116 contact wings 110 of the heat sink 108 to apply a permanent downward force to the TIM layer to enable the low thermal resistance connection. The leaf springs 116 are secured to the printed circuit board 124 by mounting screws 128 that extend through retaining washers 132 and holes 136 in the printed circuit board 124 and secure to nuts 140 mounted on a backing plate 144.

The holes 136 are located near the integrated circuit component 148 to allow the leaf spring 116 to provide a desired amount of force to the heat sink wings 110, which is translated by the heat sink into a downward force on the TIM layer. These holes 136 are also close enough to the integrated circuit component 148 such that they reside in the “breakout” region of the printed circuit board associated with the integrated circuit component 148. The breakout region of a printed circuit board associated with an integrated circuit component is the region of the board in the vicinity of the integrated circuit component where the signal routing is dense due to the need to route (a potentially very large number of) high-speed input and output, power, ground, and other signals between the integrated circuit component and other components. The breakout region can be defined as the region of the printed circuit board where at least 90% of the area of at least one interconnect layer is consumed by power, signal, and/or ground traces routed with minimum width and spacing as defined by printed circuit board design rule constraints. Thermal management solution attachment mechanisms consuming printed circuit board area (e.g., holes 136) in a breakout region can result in a larger (the breakout region may consume a larger area) or thicker (more printed circuit board layers may be needed to relieve routing congestion in the breakout area) printed circuit board.

Approaches other than that illustrated in FIG. 1 may be used to attach the thermal management solution 104 to the printed circuit board 124 and to generate a permanent force on the heatsink 108. Coil springs, conical springs, or other loading mechanism structures may be used instead of leaf springs 116. The heatsink or cold plate 108 may be attached to a support frame or other stiffening structure, onto which the loading mechanism force is applied. A backing plate 144 may be absent, with the nuts 140 instead secured directly to the printed circuit board 124 by various means (e.g., solder attach, or mechanical press fit). These features may be utilized in any combination with each other or those described above in the discussion of FIG. 1. A common factor among these approaches is that the structure 100 employs a permanent downward force on the heat sink 108 to ensure a reliable thermally conductive connection through the TIM layer to the integrated circuit component 148.

FIG. 2 illustrates an exploded view of a first example structure comprising a thermal management solution directly bonded to an integrated circuit component by a TIM layer. The structure 200 comprises a thermal management solution 204 for an integrated circuit component 248. The thermal management solution 204 comprises a pair of heat pipes 212 attached to a heat sink 208 and transports heat generated by the integrated circuit component 248 to a heat exchanger 252 located remotely to the integrated circuit component 248. The heat exchanger 252 is attached to a bottom surface 262 of the heat pipes 212 that faces the printed circuit board 224 and comprises a series of fins 253 connected by a plate 254 at the ends of the fins 253 that are distal from the heat pipes 212. In other embodiments, the heat exchanger 252 could take other suitable forms. An air mover (not shown) blows air over or through the heat exchanger 252 and through a vent in the housing (also not shown) of the computing system in a direction indicated by arrows 270 to remove heat generated by the integrated circuit component 248 from the computing system. The heat sink 208 along with any of the heat sinks described or referenced herein can comprise copper or another suitable metal.

The integrated circuit component 248 is attached to a printed circuit board 224 and is a packaged component comprising integrated circuit dies 220. A TIM layer (not shown in FIG. 2) is disposed between the heat sink 208 and the integrated circuit component 248 to provide a low thermal resistance and mechanical bond between the components. The TIM layer thus acts to keep the heat sink 208 attached to the integrated circuit component 248 during the operation of the computing system. TIMs that can bond a heat sink to an integrated circuit component include adhesives and low-temperature solders. Additional TIMs that can bond a heat sink to an integrated circuit component are discussed below. In contrast, the TIM layer used in FIG. 1 that requires the application of a permanent force to provide a reliable low thermal resistance connection can be a paste, liquid, grease, or another material that does not possess mechanical bonding properties or possesses weaker bonding properties than a TIM used in the structure illustrated in FIG. 2.

Because of the bonding properties of the TIM layer used, the structure 200 may not need a physical component (e.g., leaf spring, coil spring, conical spring, support frame, or other structure or loading mechanism) to apply a downward force to the heat sink 208 to ensure that the TIM layer provides a reliable thermally conductive connection. For example, the structure 200 does not comprise leaf springs that contact the wings 210 of the heat sink 208 to provide a permanent downward force to the TIM layer. The absence of a physical component that applies a downward force to the heat sink 208 eliminates the need for attachment mechanisms that consume area of the printed circuit board 224 in the breakout region associated with the integrated circuit component 248.

The thermal management solution 204 is attached to the printed circuit board 224 by attachment of the heat exchanger 252 to the printed circuit board 224. The heat exchanger 252 can be attached to the printed circuit board 224 by a bonding material 256, such as tape, adhesive, epoxy, or sealant. In other embodiments, other attachment mechanisms, such as fasteners, can be used to attach the heat exchanger 252 to the printed circuit board 224. In some embodiments, the attachment mechanism used to attach the heat exchanger 252 to the board 224 can thermally isolate the heat exchanger 252 from the printed circuit board 224 to a degree. Such thermally isolating attachment mechanisms can comprise, for example, plastic screws, plastic clips, or a bonding material having a low thermal conductivity, such as bonding material having a thermal conductivity in the range of 0.02-20 W/m·K.

The heat exchanger 252 attaches to the printed circuit board 224 at one or more points where the printed circuit board area utilized by the attachment mechanism does not impact signal routing in the integrated circuit component 248 being cooled or impacts the signal routing to a lesser extent than do screw holes located in a breakout region. For example, the heat exchanger 252 attachment points can be located beyond the breakout region associated with the integrated circuit component 248. The extent to which a breakout region can extend from an integrated circuit component can vary from one computing system design to another. In various embodiments, the breakout region can extend about 15, 30, or 50 millimeters from the edge of an integrated circuit component. In some embodiments, the heat exchanger 252 can attach to the printed circuit board 224 outside of a region where signal routing occurs between the integrated circuit component 248 and another integrated circuit component located on the printed circuit board.

FIG. 3 illustrates an exploded view of a second example structure comprising a thermal management solution directly bonded to an integrated circuit component by a TIM layer. The structure 300 is a variation of the structure 200 of FIG. 2 with the heat exchanger 252 attached to a top surface 258 of the heat pipes 212 as opposed to the bottom surface 262, with the heat pipes 212 attaching to the printed circuit board 224 instead of the heat exchanger 252. The heat pipes 212 are attached to the printed circuit board 224 by a bonding material 256, such as tape, adhesive, epoxy, or sealant. In other embodiments, the heat pipes 212 can be attached to the printed circuit board by any other attachment mechanism described or referenced herein, such as by screws that attach to a mounting bracket attached to the heat pipes 212. The attachment mechanism for the heat pipes 212 may thermally isolate the heat pipes 212 from the printed circuit board 224 to a degree. A thermally isolating heat pipe attachment mechanism can comprise, for example, a low thermal conductivity material such as stainless steel, plastic, low thermal conductivity foam with a pressure-sensitive adhesive film, or any other low thermal conductivity attachment mechanism described or referenced herein.

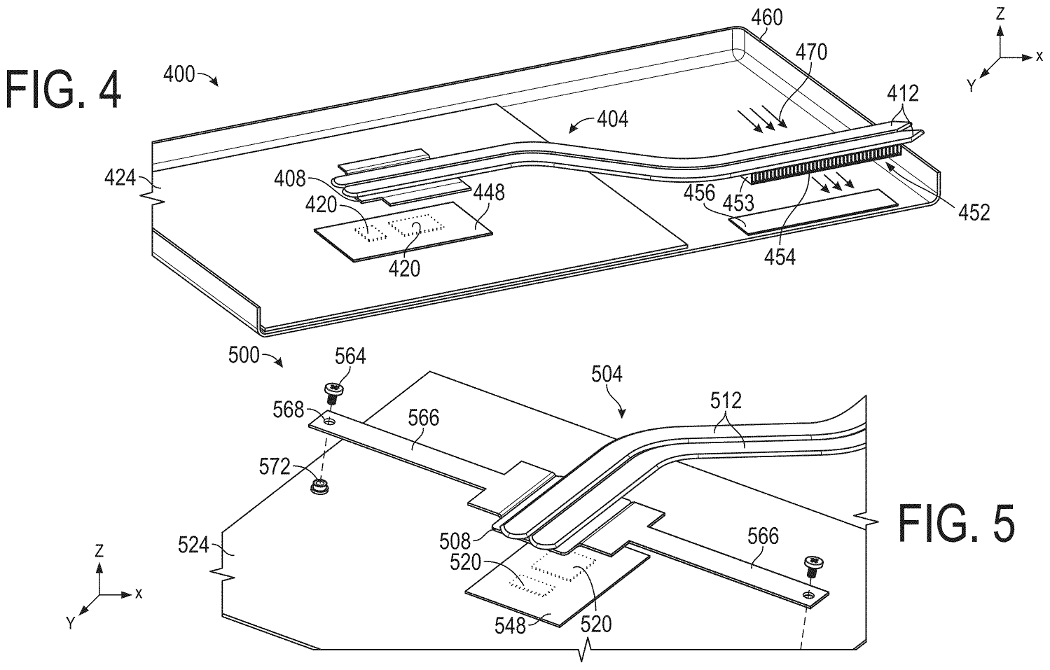

FIG. 4 illustrates an exploded view of a third example structure comprising a thermal management solution directly bonded to an integrated circuit component by a TIM layer. The structure 400 is similar to the structure 200 illustrated in FIG. 2 but with the thermal management solution mechanically attached to a system chassis instead of a printed circuit board. The thermal management solution 404 comprises a pair of heat pipes 412 attached to a heat sink 408 and transports heat generated by an integrated circuit component 448 to a heat exchanger 452 located remotely to the integrated circuit component 448. The heat exchanger 452 comprises a series of fins 453 connected by a plate 454 at the ends of the fins 453 that are distal from the heat pipes 412. An air mover (not shown) blows air over or through the heat exchanger 452 and through a vent in the housing of the computing system (also not shown) in a direction indicated by arrows 470 to remove heat from the computing system.

The integrated circuit component 448 is attached to a printed circuit board 424 and is a packaged component comprising integrated circuit dies 420. A TIM layer (not shown in FIG. 4) is disposed between the heat sink 408 and the integrated circuit component 448 to provide a low thermal resistance and strong mechanical connection between the components.

The thermal management solution 404 is attached to the chassis 460 by attachment of the heat exchanger 452 to the chassis 460. The heat exchanger 452 is attached to the chassis 460 by a bonding material 456, such as tape, adhesive, epoxy, or sealant. In other embodiments, other attachment mechanisms, such as fasteners, can be used to attach the heat exchanger 452 to the printed circuit board 424. In some embodiments, the attachment mechanism used to attach the heat exchanger 452 can thermally isolate the heat exchanger 452 from the chassis 460 to a degree and can comprise any of the thermally isolating attachment mechanisms described or referenced herein. Thermal isolation of the heat exchanger 452 from the chassis 460 can aid in preventing a hot spot on an external surface of the chassis and keep the computing system within skin temperature thermal limits. By attaching the thermal management solution 404 to the chassis 460 (by attachment of the heat exchanger 452 to the chassis 460) instead of the printed circuit board 424, area of the printed circuit board 424 is not consumed by a thermal management solution attachment mechanism and printed circuit board signals can be routed during the printed circuit board design phase without being impacted by the presence of thermal management solution attachment mechanisms. In other embodiments, the heat pipes 412 can attach to the chassis 460 instead of or in addition to the heat exchanger 452.

FIG. 5 illustrates an exploded view of a fourth example structure comprising a thermal management solution directly bonded to an integrated circuit component by a TIM layer. The structure 500 comprises a thermal management solution 504 that provides cooling to an integrated circuit component 548 and comprises a pair of heat pipes 512 attached to a heat sink 508 and transports heat generated by an integrated circuit component 548 to a heat exchanger (not shown) located remotely to the integrated circuit component 548. The heat sink 508 comprises structural extensions 566 that extend away from the integrated circuit component 548. The integrated circuit component 548 is attached to a printed circuit board 524 and is a packaged component comprising integrated circuit dies 520. A TIM layer (not shown in FIG. 5) is disposed between the heat sink 508 and the integrated circuit component 548 to provide a low thermal resistance and strong mechanical connection between the components.

The thermal management solution 504 is attached to the printed circuit board 524 through attachment of heat sink extensions 566 to the printed circuit board 524 or system chassis (not shown). The heat sink extensions 566 are attached by screws 564 that extend through holes 568 in the heat sink extensions 566 and fasten to standoffs 572 mounted on a surface of the printed circuit board 524. The heat sink extensions 566 can be attached to the printed circuit board 524 using other attachment mechanisms such as a bonding material (e.g., tape, adhesive, epoxy, sealant) in other embodiments. In some embodiments, the attachment mechanism used to attach the heat sink extensions 566 from the printed circuit board 524 to a degree and can comprise any of the thermally isolating attachment mechanisms described or referenced herein.

The attachment of the heat sink extensions 566 to the printed circuit board 524 is not intended to generate a permanent downward force on the TIM layer. Rather, the mechanical attachments of the heat sink extensions 566 to the printed circuit board 524 are intended to provide lateral X-Y positioning control of a thermal management solution and to prevent lateral slip or shear of the thermal management solution in the presence of vibration or shock events.

Like the locations of the heat pipe and heat exchanger attachment points in FIGS. 2-4, the locations at which heat sink extensions 566 are attached to the printed circuit board 524 are located beyond the breakout region associated with integrated circuit component 548 or are located outside of a region where signal routing occurs between the integrated circuit component 248 and another integrated circuit component located on the printed circuit board 524.

While FIGS. 2-5 illustrate several embodiments in which thermal management solutions are directly bonded to an integrated circuit component and attached to a printed circuit board or system chassis at one or more locations remote to the integrated circuit component, other variations are possible. For example, FIGS. 2-5 illustrate a thermal management solution comprising a pair of heat pipes, but in other embodiments, the thermal management solution can comprise another heat transfer device (such as a vapor chamber) comprising an internal cavity containing a working fluid that aids in the transport of heat by transitioning between its liquid and gas phases.

For example, while FIGS. 2-4 illustrate a pair of heat pipes extending in one direction away from an integrated circuit component to a single heat exchanger, in other embodiments, a thermal management solution can comprise heat pipes extending in multiple directions away from an integrated circuit component to multiple heat exchangers. In such embodiments, the thermal management solution can attach to a printed circuit board and/or a system chassis through attachment of heat exchanger(s) or heat pipe(s) to the printed circuit board or system chassis. The locations of these thermal management solution attachment points are beyond the breakout region associated with the integrated circuit component to be cooled by the thermal management solution or outside of the regions where signal routing occurs between the integrated circuit component and another integrated circuit component. For example, a thermal management solution can comprise two pairs of heat pipes with each pair of heat pipes extending in a different direction from the integrated circuit component. Each pair of heat pipes can attach to a separate heat exchanger and each heat exchanger can attach to a system chassis.

Similarly, while FIG. 5 illustrates a heat sink attached to a printed circuit board through attachment of two heat sink extensions extending in opposite directions from the integrated circuit component, a heat sink can comprise one or more extensions that extend in one or more different directions from the integrated circuit component. These extensions can each be attached to a system chassis and/or the printed circuit board at locations beyond the breakout regions associated with the integrated circuit component or outside of the region where signal routing occurs between the integrated circuit component being cooled by the thermal management solution and another integrated circuit component. For example, a heat sink could be attached to a printed circuit board via attachment of four heat sink extensions that extend from the integrated circuit component in a cross or “X” pattern.

Although FIGS. 2-5 illustrate a thermal management solution with only heat pipes, a heat exchanger, or heat sink extensions being attached to a printed circuit board or a chassis, in other embodiments, a thermal management solution can be attached to a printed circuit board and/or system chassis by attachment of any combination of heat pipes, vapor chambers, heat exchangers, heat spreaders, and heat sink extensions attachment to the printed circuit board and/or the system chassis. For example, in some embodiments, a thermal management solution can comprise a first heat exchanger attached to a system chassis and a second heat exchanger attached to a printed circuit board beyond the breakout region of the integrated circuit component being cooled by the thermal management solution. In other embodiments, a thermal management solution may comprise heat pipes attached to a heat sink and a heat spreader, the heat spreader attached to a printed circuit board at a location remote to the integrated circuit component being cooled by the thermal management solution. In still other embodiments, a thermal management solution can comprise a vapor chamber attached to a heat sink and a heat exchanger, the heat exchanger attached to a system chassis at a location remote to the integrated circuit component being cooled by the thermal management solution. Further, in embodiments where a thermal management solution attaches to a printed circuit board and/or system chassis through attachment of one or more heat pipes to the printed circuit board and/or system chassis, it is not necessary that heat pipe attach locations are at the end of a heat pipe. In some embodiments, a heat pipe can attach to a printed circuit board or system chassis at intermediate points along the heat pipe between an integrated circuit component and a far end of the heat pipe. A heat pipe can be attached at an intermediate point to a printed circuit board or system chassis by a mounting bracket or other component attached to the heat pipe that is in turn attached to the printed circuit board or system chassis.

In some embodiments, the TIM layer that can provide a low thermal resistance and strong mechanical connection between a heat sink and an integrated circuit component (e.g., the TIM layers used in the structures illustrated in FIGS. 2-5) can comprise various adhesives, low-temperature solders, or other suitable materials that can provide a low thermal resistance and strong mechanical bond. TIM layer adhesives can comprise dispense-type (1-part and 2-part) and film-type adhesives, such as epoxy, silicone, urethane, or acrylate-based adhesives comprising one or more thermally conductive fillers. These thermally conductive fillers can include, for example, a metal (e.g., copper, silver, aluminum), liquid metal, carbon (e.g., graphite, carbon nanotubes, carbon fibers), or a ceramic (e.g., boron nitride (BN), boron arsenide (BAs), aluminum nitride (AlN), aluminum oxide (Al₂O₃)). In embodiments where the TIM layer comprises liquid metal, the liquid metal can comprise gallium or an alloy of gallium, such as, for example, alloys of gallium and indium, eutectic alloys of gallium, indium, and tin, and eutectic alloys of gallium, indium, and zinc.

In embodiments where the TIM layer comprises a low-temperature solder, the low-temperature solder can comprise an indium alloy. The liquidous point of the indium alloy can be tuned to be between 60-200° C. based on the metal(s) with which indium is alloyed. In some embodiments, the indium alloy can comprise bismuth and/or tin additives. In other embodiments where the TIM layer comprises a low-temperature solder, the low-temperature solder can comprise a gallium-silver alloy. In some embodiments, a gallium-silver alloy can be formed as follows. Silver is plated or sputtered onto an integrated circuit component and a heat sink. Gallium or a gallium-silver alloy is then dispensed on the silver on the integrated circuit component. The gallium or gallium-based alloy spontaneously wets the silver, allowing the TIM layer to be self-leveling. The heat sink is then placed on the integrated circuit component and a light load is applied (by a fixture, for example). At room temperature (e.g., 30° C.), the gallium alloys with the silver on the heat sink, resulting in a high-temperature stable bond. The liquidous point of the gallium-silver alloy can be tuned to be between 80-450° C.

Some of the TIM layers disclosed herein may require the temporary application of a light load during assembly to generate a bond layer of a desired thickness. After curing or solidification of the TIM, this light load is removed. The application of a light and temporarily-applied load is different from the permanent load applied to TIMs that do not possess the ability to provide a mechanical bond between components, such as the TIM layers used in the structure of FIG. 1.

The thermal management solutions described herein can be attached to a printed circuit board or system chassis at one or more mounting locations using, for example, brackets, tabs, fasteners, clips, compression pads, pressure-sensitive adhesives (PSAs), bonding materials, one or more other suitable attachment mechanisms, or any combination thereof.

The technologies described herein can be implemented in any of a variety of computing systems, including mobile computing systems (e.g., smartphones, handheld computers, tablet computers, laptop computers, portable gaming consoles, 2-in-1 convertible computers, portable all-in-one computers), non-mobile computing systems (e.g., desktop computers, servers, workstations, stationary gaming consoles, set-top boxes, smart televisions, rack-level computing solutions (e.g., blade, tray, or sled computing systems)), and embedded computing systems (e.g., computing systems that are part of a vehicle, smart home appliance, consumer electronics product or equipment, manufacturing equipment). As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

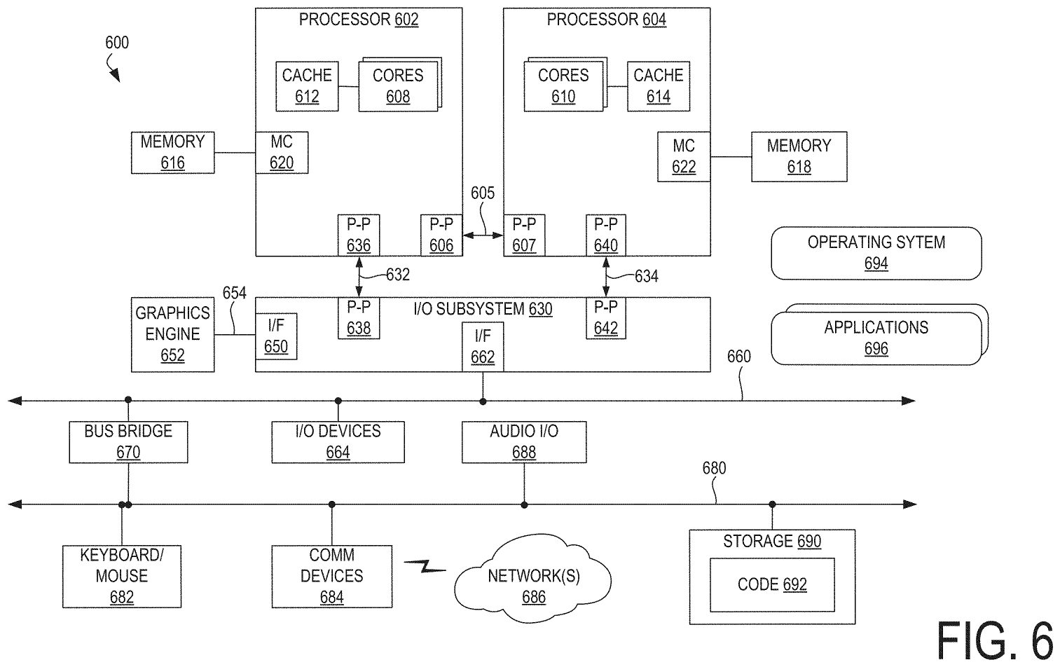

FIG. 6 is a block diagram of a second example computing system in which technologies described herein may be implemented. Generally, components shown in FIG. 6 can communicate with other shown components, although not all connections are shown, for ease of illustration. The computing system 600 is a multiprocessor system comprising a first processor unit 602 and a second processor unit 604 comprising point-to-point (P-P) interconnects. A point-to-point (P-P) interface 606 of the processor unit 602 is coupled to a point-to-point interface 607 of the processor unit 604 via a point-to-point interconnection 605. It is to be understood that any or all of the point-to-point interconnects illustrated in FIG. 6 can be alternatively implemented as a multi-drop bus, and that any or all buses illustrated in FIG. 6 could be replaced by point-to-point interconnects.

The processor units 602 and 604 comprise multiple processor cores. Processor unit 602 comprises processor cores 608 and processor unit 604 comprises processor cores 610. Processor cores 608 and 610 can execute computer-executable instructions in a manner similar to that discussed below in connection with FIG. 6, or other manners.

Processor units 602 and 604 further comprise cache memories 612 and 614, respectively. The cache memories 612 and 614 can store data (e.g., instructions) utilized by one or more components of the processor units 602 and 604, such as the processor cores 608 and 610. The cache memories 612 and 614 can be part of a memory hierarchy for the computing system 600. For example, the cache memories 612 can locally store data that is also stored in a memory 616 to allow for faster access to the data by the processor unit 602. In some embodiments, the cache memories 612 and 614 can comprise multiple cache levels, such as level 1 (L1), level 2 (L2), level 3 (L3), level 4 (L4) and/or other caches or cache levels. In some embodiments, one or more levels of cache memory (e.g., L2, L3, L4) can be shared among multiple cores in a processor unit or among multiple processor units in an integrated circuit component. In some embodiments, the last level of cache memory on an integrated circuit component can be referred to as a last level cache (LLC). One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

Although the computing system 600 is shown with two processor units, the computing system 600 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 600 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

The processor units 602 and 604 can be located in a single integrated circuit component (such as a multi-chip package (MCP) or multi-chip module (MCM)) or they can be located in separate integrated circuit components. An integrated circuit component comprising one or more processor units can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor unit, or on one or more integrated circuit dies separate from the integrated circuit dies comprising the processor units. In some embodiments, these separate integrated circuit dies can be referred to as “chiplets”. In some embodiments where there is heterogeneity or asymmetry among processor units in a computing system, the heterogeneity or asymmetric can be among processor units located in the same integrated circuit component. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Processor units 602 and 604 further comprise memory controller logic (MC) 620 and 622. As shown in FIG. 6, MCs 620 and 622 control memories 616 and 618 coupled to the processor units 602 and 604, respectively. The memories 616 and 618 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 620 and 622 are illustrated as being integrated into the processor units 602 and 604, in alternative embodiments, the MCs can be external to a processor unit.

Processor units 602 and 604 are coupled to an Input/Output (I/O) subsystem 630 via point-to-point interconnections 632 and 634. The point-to-point interconnection 632 connects a point-to-point interface 636 of the processor unit 602 with a point-to-point interface 638 of the I/O subsystem 630, and the point-to-point interconnection 634 connects a point-to-point interface 640 of the processor unit 604 with a point-to-point interface 642 of the I/O subsystem 630. Input/Output subsystem 630 further includes an interface 650 to couple the I/O subsystem 630 to a graphics engine 652. The I/O subsystem 630 and the graphics engine 652 are coupled via a bus 654.

The Input/Output subsystem 630 is further coupled to a first bus 660 via an interface 662. The first bus 660 can be a Peripheral Component Interconnect Express (PCIe) bus or any other type of bus. Various I/O devices 664 can be coupled to the first bus 660. A bus bridge 670 can couple the first bus 660 to a second bus 680. In some embodiments, the second bus 680 can be a low pin count (LPC) bus. Various devices can be coupled to the second bus 680 including, for example, a keyboard/mouse 682, audio I/O devices 688, and a storage device 690, such as a hard disk drive, solid-state drive, or another storage device for storing computer-executable instructions (code) 692 or data. The code 692 can comprise computer-executable instructions for performing methods described herein. Additional components that can be coupled to the second bus 680 include communication device(s) 684, which can provide for communication between the computing system 600 and one or more wired or wireless networks 686 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 602.11 standard and its supplements).

In embodiments where the communication devices 684 support wireless communication, the communication devices 684 can comprise wireless communication components coupled to one or more antennas to support communication between the computing system 600 and external devices.

The system 600 can comprise removable memory such as flash memory cards (e.g., SD (Secure Digital) cards), memory sticks, Subscriber Identity Module (SIM) cards). The memory in system 600 (including caches 612 and 614, memories 616 and 618, and storage device 690) can store data and/or computer-executable instructions for executing an operating system 694 and application programs 696. Example data includes web pages, text messages, images, sound files, and video data to be sent to and/or received from one or more network servers or other devices by the system 600 via the one or more wired or wireless networks 686, or for use by the system 600. The system 600 can also have access to external memory or storage (not shown) such as external hard drives or cloud-based storage.

The computing system 600 can support various additional input devices, such as a touchscreen, microphone, camera, stereoscopic camera, touchpad, trackpad, proximity sensor, light sensor, and one or more output devices, such as one or more speakers or displays. Any of the input or output devices can be internal to, external to, or removably attachable with the system 600. External input and output devices can communicate with the system 600 via wired or wireless connections.

It is to be understood that FIG. 6 illustrates only one example computing system architecture. Computing systems based on alternative architectures can be used to implement technologies described herein. For example, instead of the processors 602 and 604 and the graphics engine 652 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 6. Moreover, the illustrated components in FIG. 6 are not required or all-inclusive, as shown components can be removed and other components added in alternative embodiments.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

Example 1 is an apparatus comprising: an integrated circuit component; a printed circuit board, the integrated circuit component attached to the printed circuit board, the printed circuit board comprising a breakout region associated with the integrated circuit component; a heat sink; a heat transfer device comprising an internal cavity containing a working fluid, the heat transfer device attached to the heat sink; and a layer comprising a thermal interface material, the layer comprising the thermal interface material disposed between the heat sink and the integrated circuit component; wherein the heat transfer device is attached to the printed circuit board beyond the breakout region of the printed circuit board.

Example 2 comprises the apparatus of Example 1, wherein the heat transfer device is attached to the printed circuit board at one or more heat transfer device attachment points, and wherein individual of the heat transfer device attachment points are located more than 15 millimeters away from the integrated circuit component.

Example 3 comprises the apparatus of Example 1, wherein the heat transfer device is attached to the printed circuit board at one or more heat transfer device attachment points, and wherein individual of the heat transfer device attachment points are located more than 30 millimeters away from the integrated circuit component.

Example 4 comprises the apparatus of Example 1, wherein the heat transfer device is attached to the printed circuit board at one or more heat transfer device attachment points, and wherein individual of the heat transfer device attachment points are located more than 50 millimeters away from the integrated circuit component.

Example 5 comprises the apparatus of Example 1, wherein the integrated circuit component is a first integrated circuit component, wherein the apparatus further comprises a second integrated circuit component, wherein the heat transfer device is attached to the printed circuit board at one or more heat transfer device attachment points, and wherein individual of the heat transfer device attachment points are outside of one or more regions of the printed circuit board where signal routing occurs between the first integrated circuit component and the second integrated circuit component.

Example 6 comprises the apparatus of any one of Examples 2-5, further comprising a heat transfer device printed circuit board attachment means to attach the heat transfer device to the printed circuit board.

Example 7 comprises the apparatus of any one of Examples 2-5, wherein the heat transfer device is attached to the printed circuit board via a bonding material.

Example 8 comprises the apparatus of any one of Examples 2-5, wherein the heat transfer device is attached to the printed circuit board via one or more fasteners.

Example 9 is an apparatus comprising: an integrated circuit component; a printed circuit board, the integrated circuit component attached to the printed circuit board, the printed circuit board comprising a breakout region associated with the integrated circuit component; a heat sink comprising a heat sink extension that extends away from the integrated circuit component; a heat transfer device comprising an internal cavity containing a working fluid, the heat transfer device attached to the heat sink; and a layer comprising a thermal interface material, the layer comprising the thermal interface material disposed between the heat sink and the integrated circuit component; wherein the heat sink extension is not attached to the printed circuit board within the breakout region of the printed circuit board.

Example 10 comprises the apparatus of Example 9, wherein the heat sink extension is attached to the printed circuit board beyond the breakout region of the printed circuit board.

Example 11 comprises the apparatus of Example 9, wherein the heat sink extension is attached to the printed circuit board at one or more heat sink extension attachment points, and wherein individual of the heat sink extension attachment points are located more than 15 millimeters away from the integrated circuit component.

Example 12 comprises the apparatus of Example 9, wherein the heat sink extension is attached to the printed circuit board at one or more heat sink extension attachment points, and wherein individual of the heat sink extension attachment points are located more than 30 millimeters away from the integrated circuit component.

Example 13 comprises the apparatus of Example 9, wherein the heat sink extension is attached to the printed circuit board at one or more heat sink extension attachment points, and wherein individual of the heat sink extension attachment points are located more than 50 millimeters away from the integrated circuit component.

Example 14 comprises the apparatus of Example 9, wherein the integrated circuit component is a first integrated circuit component, the apparatus further comprising a second integrated circuit component, wherein the heat sink extension attaches to the printed circuit board at one or more heat sink extension attachment points, and wherein individual of the heat sink extension attachment points are outside of one or more regions of the printed circuit board where signal routing occurs between the first integrated circuit component and the second integrated circuit component.

Example 15 comprises the apparatus of Example 9, further comprising a heat sink extension printed circuit board attachment means to attach the heat sink extension to the printed circuit board.

Example 16 comprises the apparatus of Example 9, wherein the heat sink extension is attached to the printed circuit board via a bonding material.

Example 17 comprises the apparatus of Example 9, wherein the heat sink extension is attached to the printed circuit board by one or more fasteners.

Example 18 is an apparatus comprising: an integrated circuit component; a printed circuit board, the integrated circuit component attached to the printed circuit board, the printed circuit board comprising a breakout region associated with the integrated circuit component; a heat sink; a heat exchanger; a heat transfer device comprising an internal cavity containing a working fluid, the heat transfer device attached to the heat sink and the heat exchanger; and a layer comprising a thermal interface material, the layer comprising the thermal interface material disposed between the heat sink and the integrated circuit component; wherein the heat exchanger is attached to the printed circuit board beyond the breakout region of the printed circuit board.

Example 19 comprises the apparatus of Example 18, wherein the heat exchanger is attached to the printed circuit board at one or more heat exchanger attachment points, and wherein individual of heat exchanger attachment points are located more than 15 millimeters away from the integrated circuit component.

Example 20 comprises the apparatus of Example 18, wherein the heat exchanger is attached to the printed circuit board at one or more heat exchanger attachment points, and wherein individual of the heat exchanger attachment points are located more than 30 millimeters away from the integrated circuit component.

Example 21 comprises the apparatus of Example 18, wherein the heat exchanger is attached to the printed circuit board at one or more heat exchanger attachment points, and wherein individual of the heat exchanger attachment points are located more than 50 millimeters away from the integrated circuit component.

Example 22 comprises the apparatus of Example 18, wherein the integrated circuit component is a first integrated circuit component, wherein the apparatus further comprises a second integrated circuit component, wherein the heat exchanger is attached to the printed circuit board at one or more heat exchanger attachment points, and wherein individual of the heat exchanger attachment points are outside of one or more regions of the printed circuit board where signal routing occurs between the first integrated circuit component and the second integrated circuit component.

Example 23 comprises the apparatus of any one of Examples 18-22, further comprising a heat exchanger printed circuit board attachment means to attach the heat exchanger to the printed circuit board.

Example 24 comprises the apparatus of any one of Examples 18-22, wherein the heat exchanger is attached to the printed circuit board via a bonding material.

Example 25 comprises the apparatus of any one of Examples 18-22, wherein the heat exchanger is attached to the printed circuit board via one or more fasteners.

Example 26 comprises the apparatus of any one of Examples 18-25, further comprising an air mover to blow air through or over the heat exchanger.

Example 27 is an apparatus comprising: a printed circuit board; an integrated circuit component attached to the printed circuit board; a heat sink; a heat exchanger; a heat transfer device attached to the heat sink and the heat exchanger; and a chassis enclosing the integrated circuit component, the heat sink, the heat transfer device, and the heat exchanger; a layer comprising a thermal interface material, the layer comprising the thermal interface material disposed between the heat sink and the integrated circuit component; wherein the heat transfer device or the heat exchanger is attached to the chassis, and wherein the heat transfer device and the heat exchanger are not attached to the printed circuit board.

Example 28 comprises the apparatus of Example 27, further comprising a heat exchanger chassis attachment means to attach the heat exchanger to the chassis.

Example 29 comprises the apparatus of Example 27, wherein the heat exchanger is attached to the chassis.

Example 30 comprises the apparatus of Example 29, wherein the heat exchanger is attached to the chassis via a bonding material.

Example 31 comprises the apparatus of Example 29, wherein the heat exchanger is attached to the chassis via one or more fasteners.

Example 32 comprises the apparatus of Example 27, further comprising a heat transfer device chassis attachment means to attach the heat transfer device to the chassis.

Example 33 comprises the apparatus of Example 27, wherein the heat transfer device is attached to the chassis.

Example 34 comprises the apparatus of Example 33, wherein the heat transfer device is attached to the chassis via a bonding material.

Example 35 comprises the apparatus of Example 33, wherein the heat transfer device is attached to the chassis via one or more fasteners.

Example 36 comprises the apparatus of any one of Examples 1-35 wherein the heat transfer device comprises a heat pipe.

Example 37 comprises the apparatus of any one of Examples 1-35, wherein the heat transfer device comprises a vapor chamber.

Example 38 comprises the apparatus of any one of Examples 1-37, further comprising an air mover to blow air through or over the heat exchanger.

Example 39 comprises the apparatus of any one of Examples 1-38, wherein the heat exchanger comprises a plurality of fins.

Example 40 comprises the apparatus of any one of Examples 1-39, wherein the thermal interface material comprises an adhesive.

Example 41 comprises the apparatus of Example 40, wherein the adhesive comprises silicon, epoxy, urethane, or an acrylate-based adhesive.

Example 42 comprises the apparatus of Example 40, wherein the adhesive comprises a metal.

Example 43 comprises the apparatus of Example 40, wherein the adhesive comprises liquid metal.

Example 44 comprises the apparatus of Example 40, wherein the adhesive comprises gallium and another metal.

Example 45 comprises the apparatus of Example 40, wherein the adhesive comprises carbon.

Example 46 comprises the apparatus of Example 40, wherein the adhesive comprises a ceramic.

Example 47 comprises the apparatus of Example 40, wherein the adhesive comprises: boron and nitrogen; boron and arsenic; aluminum and nitrogen; or aluminum and oxygen.

Example 48 comprises the apparatus of any one of Examples 1-39, wherein the thermal interface material comprises indium and one or more additional metals.

Example 49 comprises the apparatus of Example 48, wherein the thermal interface material further comprises bismuth and/or tin.

Example 50 comprises the apparatus of any one of Examples 1-39 wherein the thermal interface material comprises gallium and silver.

Example 51 comprises the apparatus of any one of Examples 7, 16, 24, 30, or 34, wherein the bonding material has a thermal conductivity in a range of 0.02-20 W/m·K.

1. An apparatus comprising:
an integrated circuit component;
a printed circuit board, the integrated circuit component attached to the printed circuit board, the printed circuit board comprising a breakout region associated with the integrated circuit component;
a heat sink;
a heat transfer device comprising an internal cavity containing a working fluid, the heat transfer device attached to the heat sink; and
a layer comprising a thermal interface material, the layer comprising the thermal interface material disposed between the heat sink and the integrated circuit component;
wherein the heat transfer device is attached to the printed circuit board beyond the breakout region of the printed circuit board.

2. The apparatus of claim 1, wherein the heat transfer device is attached to the printed circuit board at one or more heat transfer device attachment points, and wherein individual of the heat transfer device attachment points are located more than 50 millimeters away from the integrated circuit component.

3. The apparatus of claim 1, wherein the integrated circuit component is a first integrated circuit component, wherein the apparatus further comprises a second integrated circuit component, wherein the heat transfer device is attached to the printed circuit board at one or more heat transfer device attachment points, and wherein individual of the heat transfer device attachment points are outside of one or more regions of the printed circuit board where signal routing occurs between the first integrated circuit component and the second integrated circuit component.

4. The apparatus of claim 1, further comprising a heat transfer device printed circuit board attachment means to attach the heat transfer device to the printed circuit board.

5. The apparatus of claim 1, wherein the heat transfer device comprises a heat pipe.

6. The apparatus of claim 1, wherein the heat transfer device comprises a vapor chamber.

7. The apparatus of claim 1, wherein the thermal interface material comprises:
copper;
silver;
aluminum;
gallium and another metal;
carbon;
boron and nitrogen;
boron and arsenic;
aluminum and nitrogen; or
aluminum and oxygen.

8. An apparatus comprising:
an integrated circuit component;
a printed circuit board, the integrated circuit component attached to the printed circuit board, the printed circuit board comprising a breakout region associated with the integrated circuit component;
a heat sink comprising a heat sink extension that extends away from the integrated circuit component;
a heat transfer device comprising an internal cavity containing a working fluid, the heat transfer device attached to the heat sink; and
a layer comprising a thermal interface material, the layer comprising the thermal interface material disposed between the heat sink and the integrated circuit component;
wherein the heat sink extension is attached to the printed circuit board beyond the breakout region of the printed circuit board.

9. The apparatus of claim 8, wherein the heat sink extension is attached to the printed circuit board beyond the breakout region of the printed circuit board.

10. The apparatus of claim 8, wherein the heat sink extension is attached to the printed circuit board at one or more heat sink extension attachment points, and wherein individual of the heat sink extension attachment points are located more than 50 millimeters away from the integrated circuit component.

11. The apparatus of claim 8, wherein the integrated circuit component is a first integrated circuit component, the apparatus further comprising a second integrated circuit component, wherein the heat sink extension attaches to the printed circuit board at one or more heat sink extension attachment points, and wherein individual of the heat sink extension attachment points are outside of one or more regions of the printed circuit board where signal routing occurs between the first integrated circuit component and the second integrated circuit component.

12. The apparatus of claim 8, further comprising a heat sink extension printed circuit board attachment means to attach the heat sink extension to the printed circuit board.

13. An apparatus comprising:
an integrated circuit component;
a printed circuit board, the integrated circuit component attached to the printed circuit board, the printed circuit board comprising a breakout region associated with the integrated circuit component;
a heat sink;
a heat exchanger;
a heat transfer device comprising an internal cavity containing a working fluid, the heat transfer device attached to the heat sink and the heat exchanger; and
a layer comprising a thermal interface material, the layer comprising the thermal interface material disposed between the heat sink and the integrated circuit component;
wherein the heat exchanger is attached to the printed circuit board beyond the breakout region of the printed circuit board.

14. The apparatus of claim 13, wherein the heat exchanger is attached to the printed circuit board at one or more heat exchanger attachment points, and wherein individual of heat exchanger attachment points are located more than 15 millimeters away from the integrated circuit component.

15. The apparatus of claim 13, wherein the integrated circuit component is a first integrated circuit component, wherein the apparatus further comprises a second integrated circuit component, wherein the heat exchanger is attached to the printed circuit board at one or more heat exchanger attachment points, and wherein individual of the heat exchanger attachment points are outside of one or more regions of the printed circuit board where signal routing occurs between the first integrated circuit component and the second integrated circuit component.

16. The apparatus of claim 13, further comprising a heat exchanger printed circuit board attachment means to attach the heat exchanger to the printed circuit board.

17. The apparatus of claim 13, wherein the heat exchanger comprises a plurality of fins.

18. The apparatus of claim 13, wherein the thermal interface material comprises:
indium and another metal; or
gallium and silver.

19. An apparatus comprising:
a printed circuit board;
an integrated circuit component attached to the printed circuit board;
a heat sink;
a heat exchanger;
a heat transfer device comprising an internal cavity containing a working fluid, the heat transfer device attached to the heat sink and the heat exchanger; and
a chassis enclosing the integrated circuit component, the heat sink, the heat transfer device, and the heat exchanger;
a layer comprising a thermal interface material, the layer comprising the thermal interface material disposed between the heat sink and the integrated circuit component;
wherein the heat transfer device or the heat exchanger is attached to the chassis, and wherein the heat transfer device and the heat exchanger are not attached to the printed circuit board.

20. The apparatus of claim 19, further comprising a heat exchanger chassis attachment means to attach the heat exchanger to the chassis.

21. The apparatus of claim 19, wherein the heat exchanger is attached to the chassis.

22. The apparatus of claim 19, further comprising a heat transfer device chassis attachment means to attach the heat transfer device to the chassis.

23. The apparatus of claim 19, wherein the heat transfer device is attached to the chassis.

24. The apparatus of claim 19, wherein the thermal interface material comprises:
copper;
silver;
aluminum;
gallium and another metal;
carbon;
boron and nitrogen;
boron and arsenic;
aluminum and nitrogen; or
aluminum and oxygen.

25. The apparatus of claim 19, wherein the thermal interface material comprises:
indium and another metal; or
gallium and silver.
